(19) United States
(12) Patent Application Publication
(10) Pub. No.: US 2019/0140207 A1
(43) Pub. Date: May 9, 2019

(54) METHOD FOR FABRICATING DISPLAY PANEL, DISPLAY PANEL AND DISPLAY APPARATUS

(71) Applicants: BOE TECHNOLOGY GROUP CO., LTD., Beijing (CN); ORDOS YUANSHENG OPTOELECTRONICS CO., LTD., Ordos, Inner Mongolia (CN)

(72) Inventors: Fashun LI, Beijing (CN); Xuefei BAI, Beijing (CN); Wei LI, Beijing (CN)

(21) Appl. No.: 16/099,914

(22) PCT Filed: Mar. 7, 2018
(86) PCT No.: PCT/CN2018/078255

§ 371 Date: Nov. 8, 2018

(30) Foreign Application Priority Data
Apr. 20, 2017 (CN) 201710262742.5

(51) Int. Cl. H01L 51/52; H01L 51/56; H01L 27/32

(52) U.S. Cl. CPC H01L 51/5237; H01L 27/3244; H01L 51/56

(57) ABSTRACT

Embodiments of the present disclosure provide a method for fabricating a display panel, a display panel and a display apparatus. The display panel has a display area and an encapsulation area surrounding the display area. In the method, an encapsulating adhesive is formed in the encapsulation area. A portion of the encapsulating adhesive at a corner of the encapsulation area has a recess facing toward the display area. Next, cutting lines are arranged on the encapsulating adhesive. The cutting lines at the corner of the encapsulation area extend into the recess. Next, the display panel is cut along the cutting lines. The method, the display panel and the display apparatus eliminate negative effects of encapsulation reliability test failure due to a portion of the encapsulating adhesive at a corner of the encapsulation area being prone to be cracked, and thus the yield of cutting the display panel is enhanced.

### CROSS REFERENCE TO RELATED APPLICATIONS

This patent application is a National Stage Entry of PCT/CN2018/078255 filed on Mar. 7, 2018, which claims the benefit and priority of Chinese Patent Application No. 201710262742.5 filed on Apr. 20, 2017, the disclosures of which are incorporated herein by reference in their entirety as part of the present application.

### BACKGROUND

The present disclosure relates to the field of display technologies, and more particularly, to a method for fabricating a display panel, a display panel, and a display apparatus.

With continuous development of display technologies, borders of display panels are becoming narrower, which makes it more difficult to cut the display panels.

### BRIEF DESCRIPTION

The present disclosure provides a method for fabricating a narrow-border display panel, a narrow-border display panel, and a display apparatus having the narrow-border display panel.

A first aspect of the present disclosure provides a method for fabricating a display panel. The display panel has a display area and an encapsulation area surrounding the display area. In the method, an encapsulating adhesive is formed in the encapsulation area. A portion of the encapsulating adhesive at a corner of the encapsulation area has a recess facing toward the display area. Next, cutting lines are arranged on the encapsulating adhesive. The cutting lines at the corner of the encapsulation area extend into the recess. Next, the display panel is cut along the cutting lines.

In some embodiments of the present disclosure, a height of the encapsulating adhesive ranges from 4 μm to 10 μm.

In some embodiments of the present disclosure, a width of a portion of the encapsulating adhesive outside the corner is greater than 300 μm.

In further embodiments of the present disclosure, the width of the portion of the encapsulating adhesive outside the corner ranges from 300 μm to 700 μm.

In some embodiments of the present disclosure, the display panel is an organic light emitting diode (OLED) display panel.

A second aspect of the present disclosure provides a display panel. The display panel has a display area and an encapsulation area surrounding the display area. An encapsulating adhesive is formed in the encapsulation area, and a portion of the encapsulating adhesive at a corner of the encapsulation area has a recess facing toward the display area.

In some embodiments of the present disclosure, a height of the encapsulating adhesive ranges from 4 μm to 10 μm.

In some embodiments of the present disclosure, a width of a portion of the encapsulating adhesive outside the corner is greater than 300 μm.

In further embodiments of the present disclosure, the width of the portion of the encapsulating adhesive outside the corner ranges from 300 μm to 700 μm.

In some embodiments of the present disclosure, the display panel is an OLED display panel.

A third aspect of the present disclosure provides a display apparatus. The display apparatus includes the aforementioned display panel according to the second aspect of the present disclosure.

Described above is merely an overview of the technical solutions of the present disclosure. In order to understand the technical solution of the present disclosure more clearly so as to implement the present disclosure in accordance with the contents of specification, and to make the aforementioned and other features and advantages of the present disclosure more apparent, specific embodiments of the present disclosure are provided hereinafter.

### BRIEF DESCRIPTION OF THE DRAWINGS

With the detailed description of the following exemplary embodiments, various other advantages and benefits will become apparent to an ordinary person skilled in the art. Accompanying drawings are merely for the purpose of illustrating the exemplary embodiments and should not be considered as limiting of the present disclosure. Furthermore, throughout the drawings, similar elements are indicated by similar reference signs. In the drawings:

FIG. 1 illustrates a partial cross-sectional view of an existing encapsulating adhesive;

FIG. 2 illustrates a flowchart of a method for fabricating a display panel according to an embodiment of the present disclosure;

FIG. 3 illustrates a schematic structural diagram of a silk screen according to an embodiment of the present disclosure; and

FIG. 4 illustrates a partial cross-sectional view of an encapsulating adhesive according to an embodiment of the present disclosure.

### DETAILED DESCRIPTION

The exemplary embodiments of the disclosure will be described in more details in the following with reference to the accompanying drawings. Although the accompanying drawings illustrate the exemplary embodiments of the disclosure, it should be understood that the disclosure may be implemented in various forms but not limited by the embodiments set forth herein. Instead, these embodiments are provided to make the present disclosure be understood more thoroughly, and completely convey the scope of the present disclosure to those skilled in the art.

FIG. 1 illustrates a partial cross-sectional view of a related encapsulating adhesive. As shown in FIG. 1, a portion of the encapsulating adhesive 11 at a corner of the display panel is designed as a circular arc, and the intersection of the cutting lines 111 is outside the encapsulating adhesive 11. If the display panel is cut along the edge of the encapsulating adhesive 11, the display panel cut in this cutting method has a wider border. As shown in FIG. 1, the corner of the cutting line 121 is positioned on the encapsulating adhesive 11. A narrow-border display panel may be cut by using this cutting method.

As shown in FIG. 1, if a narrow-border display panel is cut along the cutting line 121, a portion of an encapsulating adhesive at a corner of an encapsulation area is prone to be cracked, which causes encapsulation reliability test failure and makes it difficult to control a yield of cutting the display panel.

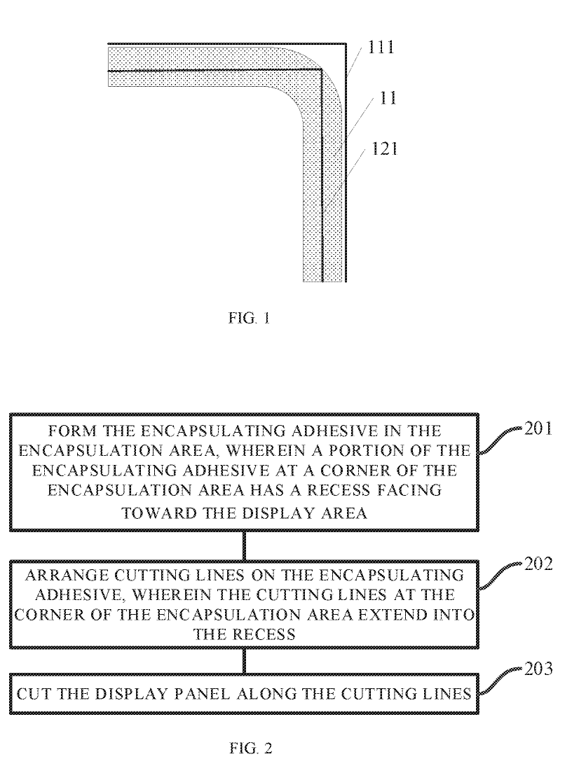

FIG. 2 illustrates a flowchart of a method for fabricating a display panel according to an embodiment of the present disclosure.

Processes of forming the encapsulating adhesive are described by taking silk screen printing as an example. However, those skilled in the art should appreciate that the encapsulating adhesive also may be formed in other methods.

In some embodiments of the present disclosure, a display motherboard includes at least one display panel, and each display panel has a display area and an encapsulation area surrounding the display area.

As shown in FIG. 2, in step 201, the encapsulating adhesive is formed in the encapsulation area. A portion of the encapsulating adhesive at a corner of the encapsulation area has a recess facing toward the display area.

First, a silk screen having inward recessed corners is fabricated, wherein patterns of the silk screen correspond to sizes and locations of the respective display panels in the display motherboard. The display panel may be an OLED display panel. The OLED display panel includes an Active Matrix/Organic Light Emitting Diode (AMOLED) display panel.

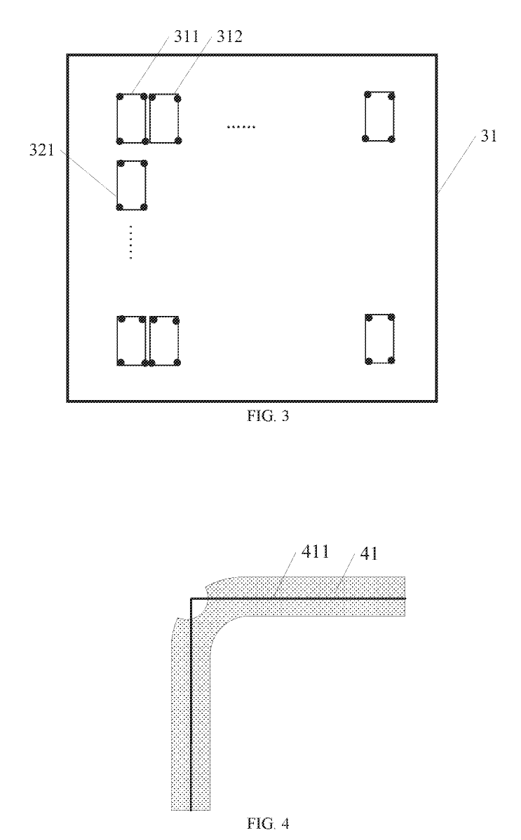

FIG. 3 illustrates a schematic structural diagram of a silk screen according to an embodiment of the present disclosure.

The display motherboard includes a plurality of display panels arranged based on the corresponding location. When the silk screen 31 as shown in FIG. 3 is fabricated, patterns in the silk screen 31 are arranged based on the corresponding locations of the respective display panels in the display motherboard. A certain distance is provided between the display panels, such that it is convenient to print the encapsulating adhesive and cut the display panel subsequently.

For example, the pattern 311 corresponds to the size and location of one display panel, the pattern 312 corresponds to the size and location of another display panel, and the pattern 321 also corresponds to one display panel. Four corners of the pattern corresponding to each display panel are designed as an inward recess facing toward the display area of the display panel. Although not illustrated, the patterns in FIG. 3 not only include the pattern 311, the pattern 312, and the pattern 313, but also include patterns corresponding to sizes and locations of the rest of display panels. Shapes and the number of the patterns in the silk screen correspond to the display panels in the display motherboard.

Next, based on the fabricated silk screen having inward recesses at its corners, the encapsulating adhesive is formed in the encapsulation area by way of silk screen printing. The fabricated silk screen has an inward recess at its corner. Therefore, a portion of the encapsulating adhesive at a corner of the encapsulation area has a recess facing toward the display area. The silk screen has four corners. Therefore, each of the four corners of the encapsulating adhesive has a recess facing toward the display area. The encapsulating adhesive includes a glass adhesive, which also may be described as a frit adhesive.

The display motherboard includes a substrate and a cover plate. Based on the fabricated silk screen having inward recesses at its corners, the encapsulating adhesive is printed in each encapsulation area on the cover plate by way of silk screen printing. Upon completion of printing, the cover plate is bonded to the substrate. Next, the encapsulating adhesive is irradiated by laser. Encapsulation of the display motherboard is completed by melting and solidifying the encapsulating adhesive from the energy of laser. The silk screen printing is implemented by using a fundamental principle that the patterned meshes are pervious to a sizing agent but the unpatterned meshes are impervious to the sizing agent. During silk screen printing, the sizing agent is poured into one end of the silk screen, and a certain pressure is applied to the sizing agent in the silk screen by using a scraper moving toward the other end of the silk screen. In the moving process, the sizing agent is squeezed by the scraper onto the cover plate from the patterned meshes. The scraper is lifted after it scrapes through the whole printing region and in the meanwhile the silk screen breaks away from the cover plate. In this way, one silk screen printing is completed.

FIG. 4 illustrates a partial cross-sectional view of an encapsulating adhesive according to an embodiment of the present disclosure.

As shown in FIG. 4, the encapsulating adhesive 41 is formed in the encapsulation area by way of silk screen printing. A portion of the encapsulating adhesive at a corner of the encapsulation area has a recess facing toward the display area.

In embodiments of the present disclosure, the height of the encapsulating adhesive may range from 4 μm to 10 μm, and the width of a portion of the encapsulating adhesive outside the corner may be greater than 300 μm. The shape and the size of the recess are set according to the actual situations, and the specific shape is not limited to the shape shown in FIG. 4. The shape of the recess may be designed as a semicircle, an arc, a semiellipse, etc. The specific shape of the recess is not limited in embodiments of the present disclosure.

In step 202, cutting lines are arranged on the encapsulating adhesive. The cutting lines at the corner of the encapsulation area extend into the recess.

In embodiments of the present disclosure, the cutting lines are arranged on the encapsulated display motherboard. To cut a narrow-border display panel, the portion of the cutting lines outside the corner is positioned on the encapsulating adhesive. To prevent the portion of the encapsulating adhesive at a corner of the encapsulation area from cracking, the cutting lines at the corner of the encapsulation area extend into the recess.

As shown in FIG. 4, the cutting lines 411 are positioned on the encapsulating adhesive 41, and the cutting lines 411 at the corner extend into the recess of the encapsulating adhesive 41.

The specific border width of the display panel is set based on the distance between the cutting lines and the display area. The size of the recess of the encapsulating adhesive 41 is related to the specific border width of the display panel.

In step 203, the display panel is cut along the cutting lines.

In embodiments of the present disclosure, each display panel is cut along the cutting lines arranged on the display motherboard to obtain a plurality of separated display panels.

Specifically, each display panel is cut by using a cutter wheel along the cutting lines to obtain a plurality of separated display panels.

In embodiments of the present disclosure, generally encapsulating adhesive is not used to form a narrow border in the encapsulation area directly by silk screen printing. Due to limitations of the existing silk screen printing, it is difficult to control width uniformity of the encapsulating adhesive when the width of the encapsulating adhesive used for a narrow border is less than or equal to 300 μm, which may result in uneven border width of the display panel after encapsulating and cutting. That is, a portion of the encapsulating adhesive has a width greater than 300 μm, while another portion of the encapsulating adhesive has a width less than 300 μm, which causes a poor encapsulation effect of the display panel. Uneven border width of the display panel may cause a lot of concave and convex points, which may have a negative effect on reliability of the display panel. Therefore, when designing the narrow-border display panel, an encapsulating adhesive whose width is greater than 300 μm is printed on the portion outside the corner, then the cutting lines are arranged on the encapsulating adhesive, and each display panel is cut along the cutting lines to obtain a plurality of separated narrow-border display panels. In this way, the obtained display panel has a better encapsulation effect, and thus requirements for the reliability of the display panel can be satisfied.

In further embodiments of the present disclosure, the width of the portion of the encapsulating adhesive outside the corner may range from 300 μm to 700 μm. As a consequence, not only the requirements for the reliability of the display panel are satisfied, but also consumption of the encapsulating adhesive is saved.

The method for fabricating a display panel according to the present disclosure eliminates negative effects of encapsulation reliability test failure due to a portion of the encapsulating adhesive at a corner of the encapsulation area being prone to be cracked, and thus the yield of cutting the display panel is enhanced.

For a brief description, the aforementioned embodiments as to the method are described as a combination of a series of actions. However, those skilled in the art should know that the embodiments of the present disclosure are not limited by sequences of the actions described above. Some steps may be performed by using other sequences or be performed simultaneously in the embodiments of the present disclosure. In addition, those skilled in the art should also learn that the embodiments set forth in this specification are exemplary embodiments, and involved actions are not necessary for the embodiments of the present disclosure.

An embodiment of the present disclosure provides a display panel. The display panel has a display area and an encapsulation area surrounding the display area. An encapsulating adhesive is formed in the encapsulation area. A portion of the encapsulating adhesive at a corner of the encapsulation area has a recess facing toward the display area.

Specifically, the display panel according to the embodiment of the present disclosure may be one display panel from the display motherboard. The display motherboard includes at least one display panel, and each display panel has a display area and an encapsulation area surrounding the display area.

The height of the encapsulating adhesive may range from 4 μm to 10 μm, and the width of a portion of the encapsulating adhesive outside the corner may be greater than 300 μm.

In an exemplary embodiment of the present disclosure, the width of the portion of the encapsulating adhesive outside the corner may range from 300 μm to 700 μm.

Those skilled in the art should appreciate that the display panel according to the embodiments of the present disclosure may be fabricated by using the method for fabricating the display panel according to the embodiments of the present disclosure, and also may be fabricated by using other fabricating methods.

The display panel according to the present disclosure eliminates negative effects of encapsulation reliability test failure due to a portion of the encapsulating adhesive at a corner of the encapsulation area being prone to be cracked, and thus the yield of cutting the display panel is enhanced.

An embodiment of the present disclosure provides a display apparatus. The display apparatus includes the above display panel.

The display apparatus may be any product or component having a display function, such as a mobile phone, a tablet computer, a TV set, a display, a notebook computer, a navigation device and so on.

The display apparatus according to the present disclosure eliminates negative effects of encapsulation reliability test failure due to a portion of the encapsulating adhesive at a corner of the encapsulation area being prone to be cracked, and thus the yield of cutting the display panel is enhanced, and consequently the yield of the display apparatus is enhanced.

Many details are discussed in the specification provided herein. However, it should be understood that the embodiments of the present disclosure can be implemented without these specific details. In some examples, the existing methods, structures and technologies are not shown in detail so as to avoid an unclear understanding of the description.

Similarly, it should be understood that, in order to simplify the disclosure and to facilitate the understanding of one or more of various aspects thereof, in the description of the aforementioned exemplary embodiments of the present disclosure, various features of the present disclosure may sometimes be grouped together into a single embodiment, accompanying figure or description thereof. However, the method of this disclosure should not be constructed as follows: the present disclosure to be protected claims more features than those explicitly disclosed in each of claims. More specifically, as reflected in the claims, the disclosed aspect is in that the features therein are less than all features of a single embodiment as disclosed above. Therefore, the claims following specific embodiments are definitely incorporated into the specific embodiments, in which each claim can be considered as a separate embodiment of the present disclosure.

In addition, it should be understood by those skilled in the art, although some aforementioned embodiments include some features included in other embodiment rather than other features, combination of features in different embodiments means that the combination is within a scope of the present disclosure and forms the different embodiments. For example, in the claims, any one of the embodiments to be protected can be used in any combination manner.

Although exemplary embodiments of this disclosure have been described, those skilled in the art may make additional amendments and modifications on these embodiments once they know the basic creative concept. Therefore, the claims are intended to be interpreted as including exemplary embodiments and all amendments and modifications falling within the scope of embodiments of this disclosure.

It is to be noted that a relational term (such as a first or a second . . . ) herein is merely intended to separate one entity or operation from another entity or operation instead of requiring or hinting any practical relation or sequence exists among these entities or operations. Furthermore, terms such as “comprise”, “include” or other variants thereof are intended to cover a non-exclusive “comprise” so that a process, a method, a product, or a device including a series of elements not only includes these elements, but also includes other elements not listed explicitly, or also includes inherent elements of the process, the method, the product, or the device. In the case of no more restrictions, elements restricted by a sentence “include a . . . ” do not exclude the fact that additional identical elements may exist in a process, a method, a product, or a device including this element.

Detailed description of the method for fabricating a display panel, the display panel and the display apparatus provided by the present disclosure is presented hereinabove, the principle and embodiment of the present disclosure is set forth by using specific examples herein, and the aforementioned embodiments are merely intended to assist in understanding the method of the present disclosure and a core concept thereof also, those of ordinary skill in the art may change, in according with the core concept of the present disclosure, the implementation method and scope of application. In conclusion, contents of this description shall not be interpreted as limiting the present disclosure.

1. A method for fabricating a display panel, the display panel having a display area and an encapsulation area surrounding the display area, wherein the method comprises:
forming an encapsulating adhesive in the encapsulation area, wherein a portion of the encapsulating adhesive at a corner of the encapsulation area has a recess facing toward the display area;
arranging cutting lines on the encapsulating adhesive, wherein the cutting lines at the corner of the encapsulation area extend into the recess; and
cutting the display panel along the cutting lines.

2. The method according to claim 1, wherein a height of the encapsulating adhesive ranges from 4 μm to 10 μm.

3. The method according to claim 1, wherein a width of a portion of the encapsulating adhesive outside the corner is greater than 300 μm.

4. The method according to claim 3, wherein the width of the portion of the encapsulating adhesive outside the corner ranges from 300 μm to 700 μm.

5. The method according to claim 1, wherein the display panel is an OLED display panel.

6. A display panel having a display area and an encapsulation area surrounding the display area, wherein an encapsulating adhesive is formed in the encapsulation area, and wherein a portion of the encapsulating adhesive at a corner of the encapsulation area has a recess facing toward the display area.

7. The display panel according to claim 6, wherein a height of the encapsulating adhesive ranges from 4 μm to 10 μm.

8. The display panel according to claim 6, wherein a width of a portion of the encapsulating adhesive outside the corner is greater than 300 μm.

9. The display panel according to claim 8, wherein the width of the portion of the encapsulating adhesive outside the corner ranges from 300 μm to 700 μm.

10. The display panel according to claim 6, wherein the display panel is an OLED display panel.

11. A display apparatus comprising the display panel according to claim 6.

12. The method according to claim 2, wherein a width of a portion of the encapsulating adhesive outside the corner is greater than 300 μm.

13. The method according to claim 12, wherein the width of the portion of the encapsulating adhesive outside the corner ranges from 300 μm to 700 μm.

14. The display panel according to claim 7, wherein a width of a portion of the encapsulating adhesive outside the corner is greater than 300 μm.

15. The display panel according to claim 14, wherein the width of the portion of the encapsulating adhesive outside the corner ranges from 300 μm to 700 μm.

16. A display apparatus comprising the display panel according to claim 7.

17. A display apparatus comprising the display panel according to claim 8.

18. A display apparatus comprising the display panel according to claim 9.

19. A display apparatus comprising the display panel according to claim 10.

20. A display apparatus comprising the display panel according to claim 14.
